(19) United States
(12) Patent Application Publication
(10) Pub. No.: US 2026/0211023 A1
(43) Pub. Date: Jul. 23, 2026

(54) REAL-TIME WILDFIRE INCIDENT MONITORING SYSTEM

(71) Applicant: DARRYL MENDIVIL, Sam Luis Obispo, CA (US)

(72) Inventor: DARRYL MENDIVIL, Sam Luis Obispo, CA (US)

(21) Appl. No.: 19/286,780

(22) Filed: Jul. 31, 2025

Related U.S. Application Data
(63) Continuation-in-part of application No. 18/916,620, filed on Oct. 15, 2024, now abandoned.
Application No. 18/916,620 is a continuation of application No. 18/365,747, filed on Aug. 4, 2023.
Application No. 18/365,747 is a continuation-in-part of application No. 17/173,144, filed on Feb. 10, 2021, now Pat. No. 12,320,834.
(60) Provisional application No. 63/549,368, filed on Feb. 2, 2024.
(60) Provisional application No. 63/590,322, filed on Oct. 13, 2023.
(60) Provisional application No. 62/972,640, filed on Feb. 10, 2020.

(51) Int. Cl. G01R 31/08; B60W 60/00

(52) U.S. Cl. CPC G01R 31/085; B60W 60/001; B60W 2300/14; B60W 2420/403

(57) ABSTRACT

A real-time incident monitoring system has a bi-spectrum infrared and visible-light camera and a wireless transmitter that transmits a video signal from the camera to a remote server. The camera is mounted in a location and position to monitor places at risk for wildfire breakout, for example, on mountaintops or near equipment such as power lines. The server monitors the infrared video signal for temperature anomalies and causes an alert to be sent to an end-user if a heat signature measured using the infrared image exceeds a predetermined level or falls outside a predetermined range, or if fire or smoke is detected. The server also provides access to live video stream and recorded video of the infrared and visible-light imaging for real-time human observation.

### RELATED APPLICATIONS

This application is a continuation-in-part of United States Utility Patent Application Ser. No. 18/916,620 for a “Real-Time Fault Monitoring System,” Filed October 15, 2024, and currently co-pending, which in turn is a continuation in part of United States Utility Patent Application Serial No. 18/365,747 for a “Real-Time Fault Detection and Infrared Inspection System,” filed August 4, 2023, and currently pending, which is a continuation in part of United States Utility Patent Application Serial No. 17/173,144 for “Real-Time Fault Detection and Infrared Inspection System,” filed February 10, 2021, now U.S. Patent No. 12,320,834, which claims priority to United States Provisional Patent Application Ser. No. 62/972,640 for “Real-Time Fault Detection and Infrared Inspection System,” filed February 10, 2020. Application Ser. No. 18/916,620 further claims priority to United States Provisional Patent Application Ser. No. 63/590,322 for a “Real-Time Wind Turbine Fault Monitoring System,” filed October 13, 2023, and United States Provisional Patent Application Ser. No. 63/549,368 for a “Real-Time Fault Monitoring System,” filed February 2, 2024. The above-mentioned applications are fully incorporated herein by reference as if set forth herein in their entirety.

### FIELD OF THE INVENTION

The present invention pertains generally to imaging systems. The present invention is more particularly related to the use of imaging systems for the detection of dangerous conditions, such as faults in electrical equipment, potential points of mechanical failure, and disasters such as wildfires. The present invention is well suited for the real-time monitoring of wildfires to provide early alerts of their existence as well as to monitor the growth and extent of fires during response.

### BACKGROUND OF THE INVENTION

Disaster response has become such an important part of modern society that a new professional field of Emergency Management is arising out of experiences of first responders together with academic and government studies of disasters and disaster response. An important part of Emergency Management and disaster response in general is preparations made before a disaster strikes, which includes efforts at early identification of potential incidents. Those involved in disaster response at all levels, including government leaders, emergency managers, and on-the-ground response personnel such as firefighters, law enforcement, and emergency medical technicians, benefit from having accurate, up-to-date information. Similar intelligence is useful to others involved in activities in which disasters need to be avoided, or for which avoiding equipment failure is important regardless of disaster risk, such as utilities, factories, and other enterprises.

Potential disasters and other failures worth avoiding include wild fires, structural failures of large buildings or other structures, failures of electrical power systems, among other incidents. Some of these are summarized below, together with efforts made to mitigate the potential issues.

Wind turbines are a popular source of clean energy and generally operate by rotors that turn wind energy into rotational energy, which is in turn converted into electricity by a generator. Modern large wind turbines can produce more than a megawatt of power, with some modern wind turbines achieving outputs of tens of megawatts.

However, wind turbines are prone to catastrophic failure. One of the most common causes of wind turbine accidents is fire. Once a fire breaks out, there is often no real option other than to wait for the fire to burn out on its own; meanwhile, if the rotor blades are turning, the generator can continue operating, creating additional heat that further weakens the structure and exacerbates the fire situation. Although many turbines include brakes, it can be difficult or impossible to quickly bring large, fast-moving blades—which extend three hundred feet or more in some turbines—to a halt. Fires tend to cause severe structural damage, often resulting in a total loss of the wind turbine.

An average of 117 documented turbine fires occur annually worldwide, with many others going unreported due to their remote locations and the lack of centralized reporting mechanisms. These fires are the second most common cause of turbine incidents globally, after blade failure, with the fires resulting in a total loss 90% of the time. Additionally, OSHA has documented incidents involving falls, electrical shocks, and arc flashes, which remain significant risks for workers in the industry.

Wind turbines are strategically placed in offshore, mountainous, or open plain locations to capture strong wind patterns. However, these environments sometimes present significant maintenance challenges. Inside the nacelle, the housing for essential components like high-voltage cabinets, issues such as overheating can lead to arc flashes and electrical fires, resulting in long downtimes due to damage to critical components. Costly repairs, operational disruptions, and safety risks for technicians are a daily challenge.

Apart from the dangers presented by structural damage, such as collapse or rotor blades flying off the tower, there is a potentially enormous economic cost to failure, since the cost of large wind turbines is in the millions of dollars, and even smaller turbines with output measured in mere kilowatts can cost fifty thousand dollars or more.

Wind turbines are strategically placed in offshore, mountainous, or open plain locations to capture strong wind patterns. However, these environments sometimes present significant maintenance challenges. Inside the nacelle, the housing for essential components like high-voltage cabinets, issues such as overheating can lead to arc flashes and electrical fires, resulting in long downtimes due to damage to critical components. Costly repairs, operational disruptions, and safety risks for technicians are a daily challenge.

Likewise, equipment failure can present problems and fire risk in other installations related to the generation and distribution of electrical power. For example, inverters used with solar arrays, transformers, power lines, high voltage power panels, and switchgears are all potential points of failure. Battery energy storage facilities can catch fire, contaminating the air and posing other regional environmental risks in addition to the fire itself resulting in electrical grid impacts, and the cost of damage to the facilities themselves can be significant. Fires in facilities using lithium-ion batteries are particularly difficult to extinguish, due in part to thermal runaway.

Wildfires are a disaster threat in many areas and can be hard to manage and cause extensive damage, as recent fires in Southern California have demonstrated. Once a fire breaks out, it becomes important to monitor the fire during the response phase. However, smoke from the fire obscures visibility, making current visual monitoring systems less than ideal.

In view of the above, it would be advantageous to provide systems that can detect and report faults in multiple types of power systems, that is, in electrical generation and distribution equipment. It would be further advantageous to provide new and improved systems for warning of and monitoring disasters such as wildfires.

### SUMMARY OF THE INVENTION

Disclosed are real-time incident monitoring systems that are useful for monitoring disasters such as wildfires, faults in electrical generation and distribution equipment, and faults in mechanical systems, and for predicting, in many cases, incidents or failures before they occur. Preferred embodiments use bi-spectrum cameras that include visible light and infrared (IR) imaging. The disclosed cameras convert IR waves in the 8-14 nanometer range into visible “heat” pictures using an uncooled microbolometer.

Every molecule in the solar system emits unique IR energy waves. And, like the visible color spectrum, every compound Absorbs, reflects or transmits IR waves in their own unique way (emissivity) which allows us to distinguish between them, e.g., a person from a tree, or a fire from a forest. When anything gets cold or heats up, its emissivity changes and this causes them stand out to the cameras. There is no need for a light source for the IR cameras to see something. Unlike night vision goggles that enhance available light, the disclosed IR Cameras see the same in pitch black as well as in daylight and camouflage does not work. The cameras can see through fog, clouds, rain, and smoke.

A preferred embodiment includes a real-time wind turbine fault monitoring system. Preferred embodiments include an infrared camera mounted in the nacelle to monitor temperatures of the components inside and a wireless transmitter that transmits a video signal from the camera to a monitoring system such as an internet-connected server.

In other preferred embodiments, the cameras are mounted in inverter cabinets for solar arrays, battery storage facilities, utility vaults, utility and transmission lines, hydroelectric power stations, battery energy storage facilities, or manufacturing facilities. An exemplary embodiment is incorporated into a manufacturing facility to streamline component manufacturing processes with efficient inspection and condition monitoring, thus protecting critical connections in order to maximize manufacturing uptime. Cameras can be mounted in multiple sites to provide real-time monitoring, e.g., in multiple solar sites, or in both solar and wind generation facilities together with utility lines, or other combinations as needed for a particular purpose.

In preferred embodiments, the server receiving the signal from the camera monitors the signal for temperature anomalies and causes an alert to be sent to an end-user if a heat signature measured using the infrared image exceeds a predetermined level or falls outside a predetermined range. In some preferred embodiments, computer vision technology incorporating machine learning is also used to monitor infrared and visible-light video signals for potential hazards, including temperature anomalies, equipment breakage, and other hazardous conditions. The server also provides access to live video stream and recorded video for both real-time human observation and the ability to analyze where and when a fault initially occurred.

In preferred embodiments, the camera is a bi-spectrum camera that captures visible light images as well as infrared, thus enabling a user to monitor both an infrared video stream and a visible light video stream.

The system provides alarm alerts with reports predicting fire hazard, arc flashes, nacelle break areas, and failures in converter cabinets and transformers.

Another preferred embodiment of a real-time incident monitoring system is useful for monitoring wildfires. Fixed and mobile bi-spectrum cameras are useful for helping agencies, utilities, and industries identify fire risks and for early fire detection that enables rapid response and effective wildfire mitigation. The thermal imaging capabilities of the cameras allow for identification of risks such as smoldering embers and overheating power lines, and can also provide views of fire or fire risks in low visibility situations, such as through smoke or fog.

Pattern recognition software, supported by artificial intelligence, automatically identifies fire and risk factors, and can distinguish people from animals, thereby helping to spot arsonists or find firefighters in danger.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 illustrates the components of a typical wind turbine;

FIG. 2 illustrates a wind turbine with on-site components of a preferred embodiment of a real-time wind turbine fault monitoring system installed;

FIG. 3 is a high-level diagram of components of a preferred embodiment of a real-time wind turbine fault monitoring system;

FIG. 4 is a diagram of a solar array;

FIG. 5 is a front view of an electronics cabinet with a bi-spectrum camera mounted on the inside of the housing door as part of a real-time fault monitoring system;

FIG. 6 illustrates a real-time fault monitoring system implemented at an electrical substation;

FIG. 7 illustrates a visible-color camera view from a real-time fault monitoring system observing a wildfire at a distance;

FIG. 8 illustrates an infrared camera view from a real-time fault monitoring system observing a wildfire at a distance;

FIG. 9 is a high-level diagram of components of a preferred embodiment of a real-time fault monitoring system;

FIG. 10 is a high-level diagram of components of a preferred embodiment of a real-time fault monitoring system in conjunction with wind turbines solar arrays and utility lines;

FIG. 11 is a front view of a bi-spectrum camera used in a preferred embodiment of a real-time wind turbine fault monitoring system;

FIG. 12 is a side view of the bi-spectrum camera of FIG. 11;

FIG. 13 is a rear view of the bi-spectrum camera of FIG. 11;

FIG. 14 illustrates a dashboard user interface for remote monitoring via a preferred embodiment of a real-time wind turbine fault monitoring system;

FIG. 15 is a flow chart illustrating an exemplary monitoring and alert process performed by a preferred embodiment of a real-time fault monitoring system;

FIG. 16 is a perspective view of a bi-spectrum varifocal camera used in a preferred embodiment of a wildfire monitoring system;

FIG. 17 is a perspective view of a compact bi-spectrum camera used in a preferred embodiment of a wildfire monitoring system;

FIG. 18 is a perspective view of a bi-spectrum camera used in a preferred embodiment of a wildfire monitoring system;

FIG. 19 is a perspective view of a skid assembly used in some preferred embodiments of a wildfire monitoring system;

FIG. 20 is a side view of the skid assembly in an extended configuration;

FIG. 21 is a side view of the skid assembly in a retracted configuration;

FIG. 22 is a diagram of a preferred embodiment of a wildfire monitoring system;

FIG. 23 is a flowchart

### DETAILED DESCRIPTION

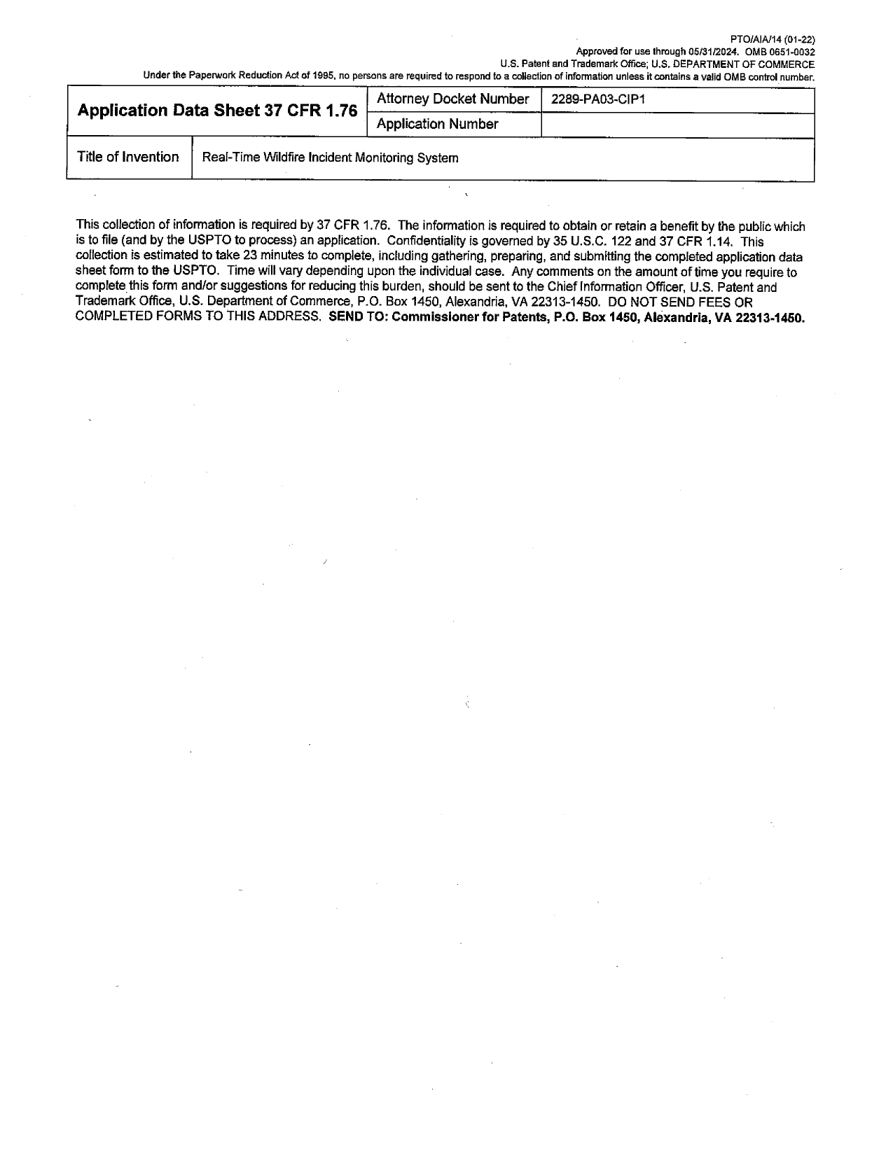

Referring initially to FIG. 1, a typical wind turbine for electricity generation is illustrated and generally labeled 10. Wind turbine 10 includes tower 12 installed on a foundation 14. At the top of tower 12 is hub 16 attaching blades 18 to nacelle 20 such that the blades 18, rotated by the wind, turn shaft 22 to provide mechanical power to generator 24. In some models, a gearbox 26 provides a transmission to provide a different rotational speed to the generator 24. At the base of tower 12 is a utility box 28 which has a converter or other hardware for adapting the generated electricity to a form desired for use, e.g., providing an appropriate frequency and phase for the electrical grid.

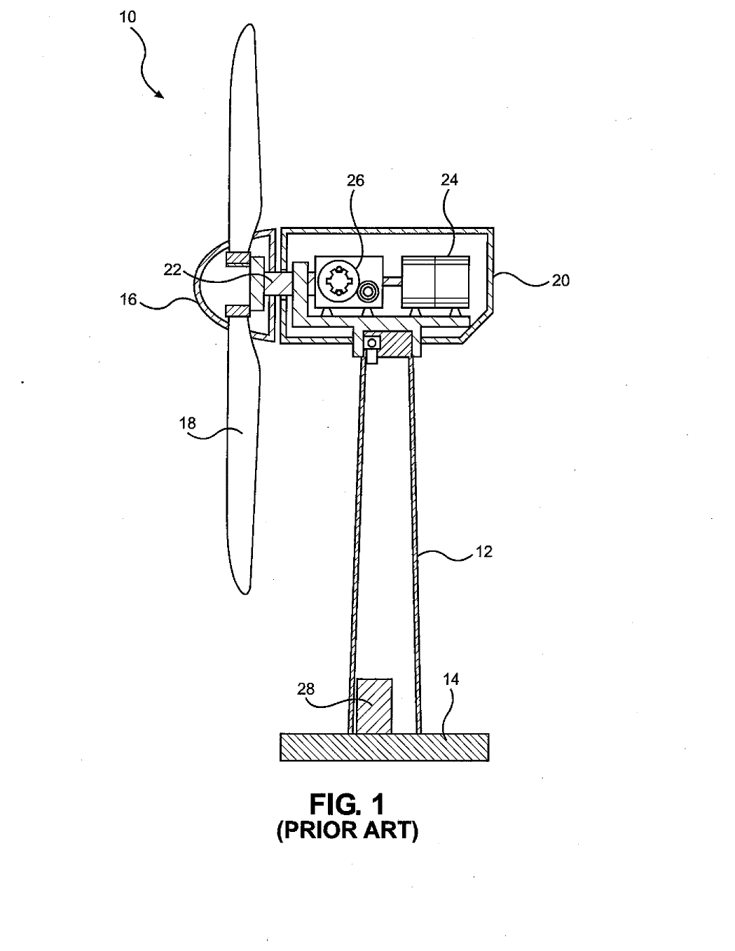

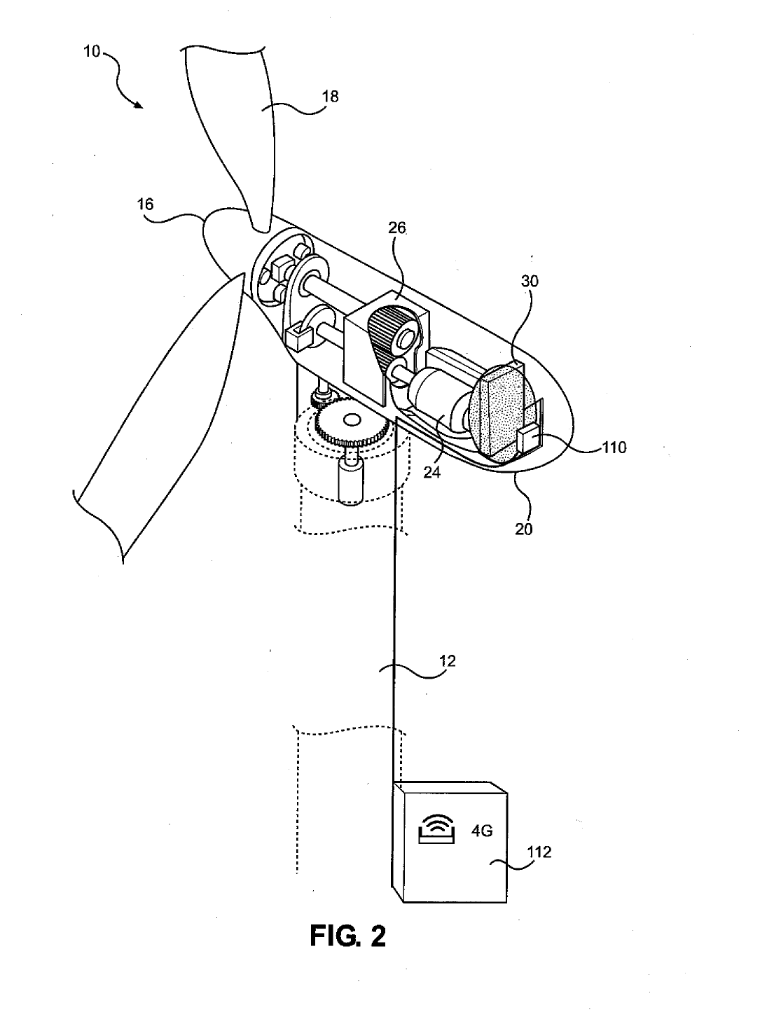

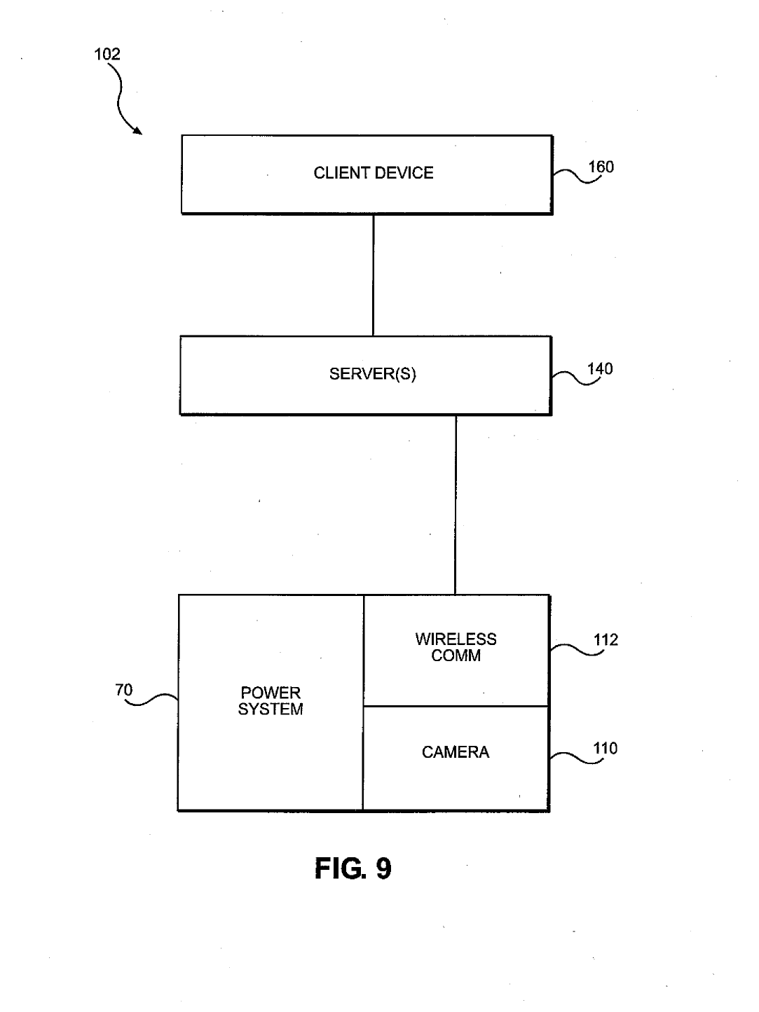

Referring now to FIG. 2, in a preferred embodiment of a real-time wind turbine fault monitoring system 100 (see FIG. 9), a camera 110 is installed in the nacelle 20 of a wind turbine 10 such that camera 110 captures images of its components, including generator 24 and associated electronics 30, as well as gearbox 26 and other contents of interest in nacelle 20.

In preferred embodiments, camera 110 has a thermal image sensor in order to capture infrared video. In this way, temperature measurements of generator 24, electronics 30, and other components inside nacelle 20 can be made. Some preferred embodiments of camera 110 also include a visible light sensor to capture black-and-white and color video from inside the nacelle 20.

Video imaging captured from camera 110 is provided to a wireless communication device 112, which sends the video signal to remote monitoring equipment, such as server 140 (as shown in FIG. 9). In a preferred embodiment, wireless communication device 112 includes a cellular modem and supporting electronics in order to send video using a network provided by a cellular carrier.

In some preferred embodiments, wireless communication device 112 is mounted at the base of tower 12, in or near utility box 28. Other embodiments in which wireless communication device 112 is located elsewhere, including near camera 110 in nacelle 20, are fully contemplated herein. Some preferred embodiments include additional cameras 110 located in areas of interest, such as in one or more of utility box 28, within tower 12, or elsewhere.

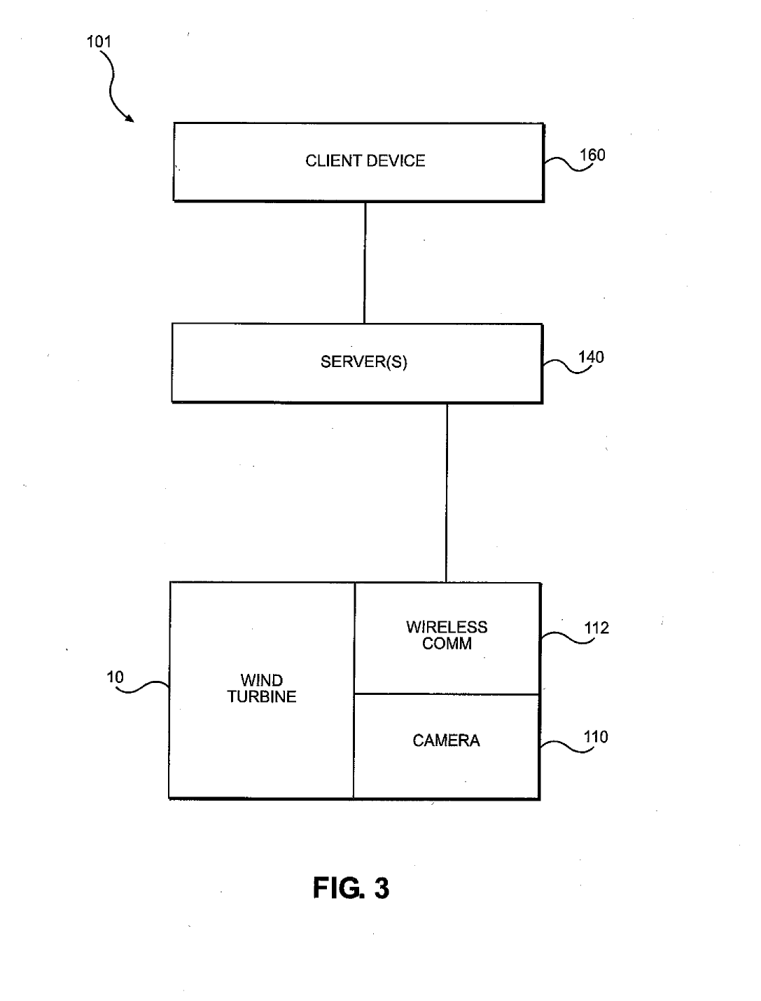

Referring now to FIG. 3, a diagram of a preferred embodiment of a real-time wind turbine fault monitoring system 101 is illustrated. Camera 110 is mounted on wind turbine 10; in preferred embodiments, camera 110 is located in the nacelle 20 (see FIG. 1), and in some preferred embodiments additional cameras 110 monitor other parts of wind turbine 10, as discussed above. Wireless communication device 112, also located on or next to wind turbine 10 in preferred embodiments, receives a video signal from camera 110 and provides it to one or more servers 140.

Although a single wind turbine 10 with an associated camera 110 and wireless communication device 112 is illustrated for clarity, preferred embodiments include systems 101 installed for use with multiple wind turbines 10, each with their own associated camera 110 or multiple cameras 110. In some embodiments, each wind turbine 10 has its own wireless communication device 112 to provide the feed from camera 110 to a server 140, while in other embodiments a wireless communication device 112 is shared between multiple wind turbines 10. For example, a wind farm may include anywhere from a few to several hundred wind turbines 10; system 101 is designed to operate with and monitor any number of desired wind turbines 10. Each wind turbine 10 is linked to server 140 or servers 140 through its own or a shared communication device 112.

In a preferred embodiment, servers 140 include a central management server, a database server, a media distribution server, and an intelligent analysis server. The intelligent analysis server provides image or pattern recognition capabilities for artificial intelligence supported monitoring, such as using deep learning algorithms to detect fire, smoke, and other potentially urgent issues. It will be apparent to one of ordinary skill in the art that these servers can share hardware, operating together on a single or a few computing devices, or each operate on their own hardware. Moreover, any of the servers can operate on multiple computing devices to provide additional computing resources as necessary for its task. They can also be implemented on cloud platforms, including “serverless” computing platforms.

In a preferred embodiment, servers 140 provide automated real-time monitoring, warning an end-user of temperature anomalies or other identified hazards, such as providing an alert when a temperature exceeds a predetermined threshold; providing an alert when smoke, fire or another anomalous situation is detected; or providing both types of alerts. In typical embodiments, these alerts are provided to a client device 160, such as a computer, tablet, mobile phone, or other computing device. Servers 140 also provides live access to infrared and visible light video feeds to an end user accessing servers 140 through a client device 160, and further provide the ability for a user using client device 160 to review recorded video from the infrared and visible light feeds. That is, video is provided both live and recorded at the same time so that a user can navigate to video captured at previous points in time, for example to research the origins of a fault.

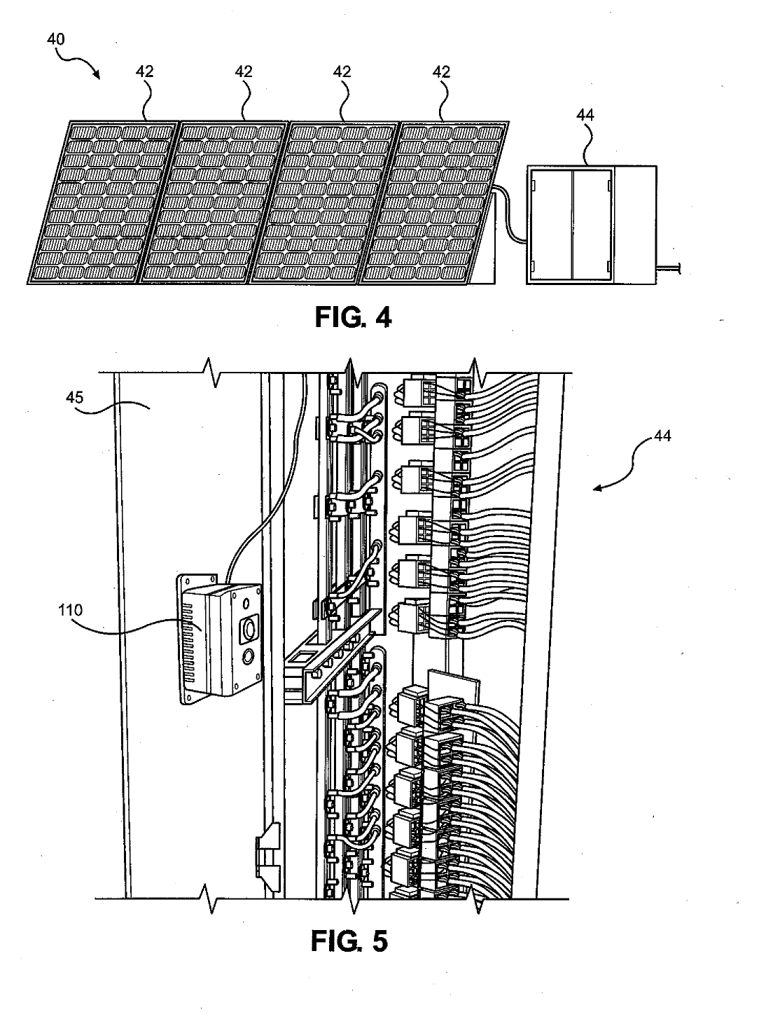

Referring now to FIG. 4, an exemplary solar array 40 is illustrated. Solar array 40 includes solar panels 42 and an inverter 44.

Referring now to FIG. 5, an electronics cabinet is illustrated with its housing door 45 open to show camera 110 mounted on the inside of door 45. The cabinet houses electronics, such as inverter 44 for a solar array 40, or electronics 30 for wind turbine 10. In this configuration, camera 110 is situated to monitor the cabinet and warn a user of temperature anomalies or other hazards as described previously with respect to wind turbine 10 (see FIG. 2).

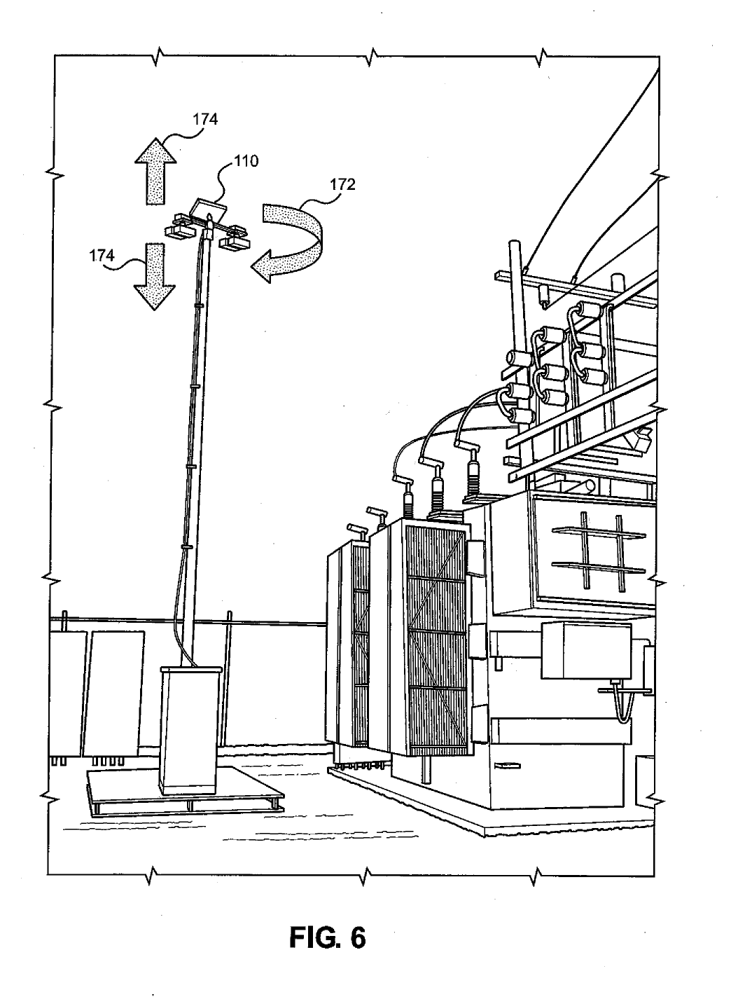

Referring now to FIG. 6, a preferred embodiment of a real-time fault monitoring system 100 is shown as implemented at a power substation. Camera 110 is mounted so that it can observe the switchgears and other components of the substation. FIG. 6 also illustrates the pan 172 and tilt 174 capabilities of camera 110, provided by the mounting equipment in preferred embodiments. Pan 172, tilt 174, and zoom capabilities allow for better observation of the power substation, or, in other embodiments, the power system being monitored, and in particular allow users to direct the camera and zoom in to better view a potential problem area. In some embodiments, the pan 172, tilt 174, and zoom capabilities further allow for external threats to be observed, e.g., by panning and zooming camera 110 to view areas outside the substation or other installation being monitored.

Although a power substation is shown, camera 110 can be mounted in a similar manner in other situations, including away from any power systems. For example, an alternative preferred embodiment of a real-time fault monitoring system includes cameras 110 mounted as illustrated in FIG. 6 on mountains or in other open areas to monitor wildfires and other hazards.

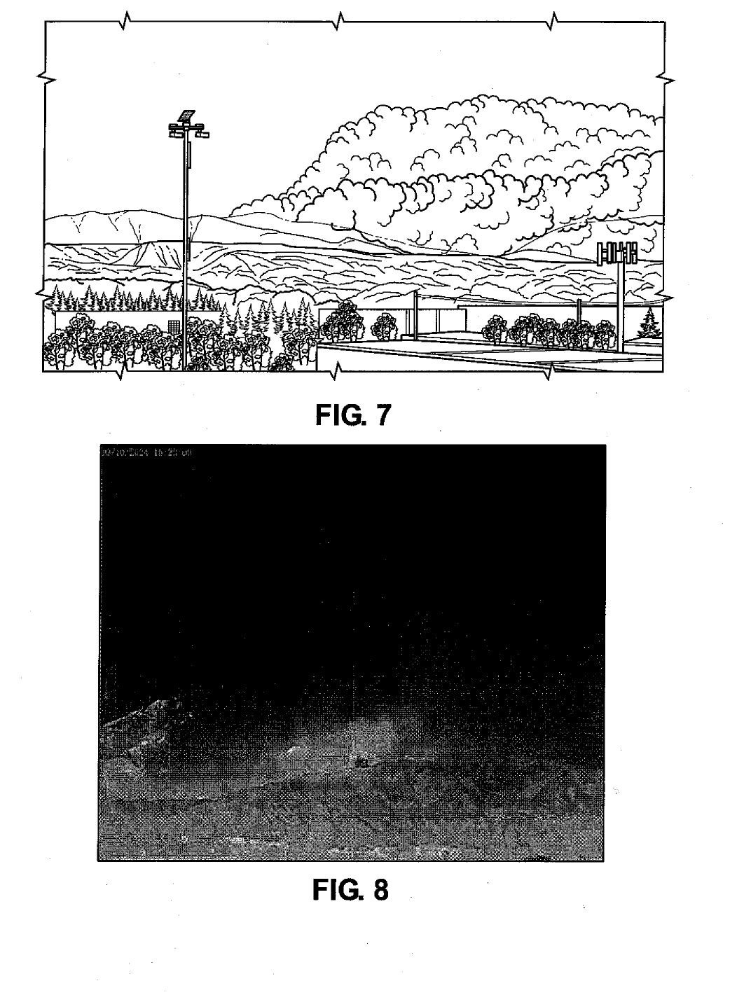

FIG. 7 illustrates a camera 110 view of a real-time fault monitoring system 100 viewing a wildfire. A camera 110 as part of a real-time fault monitoring system 100 mounted in an installation such as an electrical substation can provide a view of a wildfire in the region, as can a camera 110 installed on a mountaintop or other open area as part of a real-time fault monitoring system 100 used specifically for regional hazards such as wildfires.

A wildfire viewed from camera 110 may be obscured by smoke in the visible-light view, as seen in FIG. 7. However, the thermal or infrared view, as shown in FIG. 8, is able to observe the fire itself despite smoke obscuring the visible-light view.

Referring now to FIG. 9, a diagram of a preferred embodiment of a real-time fault monitoring system 102 is illustrated. Camera 110 is mounted on power system 70, or otherwise such that it is able to observe power system 70. Power system 70 is an apparatus related to electrical generation, storage, transmission, distribution, or use. Exemplary power systems 70 include wind turbines, solar inverters, transmission lines, transformers, switchgears, battery energy storage facilities, power panels (e.g. at manufacturing facilities), generators, and other devices for power generation, distribution, or storage. In some preferred embodiments additional cameras 110 monitor other parts of the installation in which power system 70 operates. For example, a large system generating grid power may have multiple inverters, transformers, and other equipment necessary to provide a large amount of power suitable for distribution to grid customers. Cameras 101 are used in some embodiments to monitor this equipment. Wireless communication device 112, also located on or next to power system 70 in preferred embodiments, receives a video signal from camera 110 and provides it to one or more servers 140.

Although a single power system 70 with an associated camera 110 and wireless communication device 112 is illustrated for clarity, preferred embodiments include systems 101 installed for use with multiple power systems 70 and other equipment, for example, as part of a single solar array 40 (see FIG. 4) or multiple solar arrays 40, each with their own associated camera 110 or multiple cameras 110. In some embodiments, each power system 70 or other piece of monitored equipment has its own wireless communication device 112 to provide the feed from camera 110 to a server 140, while in other embodiments a wireless communication device 112 is shared between multiple power systems 70.

In some embodiments, such as a mountaintop camera 110 for observing wildfires, power system 70 is not part of the setup. In these embodiments, wireless communication device 112 is simply attached to or otherwise located near camera 110 in order to provide communication capabilities.

In a preferred embodiment, servers 140 include a central management server, a database server, a media distribution server, and an intelligent analysis server. The intelligent analysis server provides image or pattern recognition capabilities for artificial intelligence supported monitoring, such as using deep learning algorithms to detect fire, smoke, and other potentially urgent issues. It will be apparent to one of ordinary skill in the art that these servers can share hardware, operating together on a single or a few computing devices, or each operate on their own hardware. Moreover, any of the servers can operate on multiple computing devices to provide additional computing resources as necessary for its task. They can also be implemented on cloud platforms, including “serverless” computing platforms.

In a preferred embodiment, servers 140 provide automated real-time monitoring, warning an end-user of temperature anomalies or other identified hazards, such as providing an alert when a temperature exceeds a predetermined threshold; providing an alert when smoke, fire or another anomalous situation is detected; or providing both types of alert. In typical embodiments, these alerts are provided to a client device 160, such as a computer, tablet, mobile phone, or other computing device. Servers 140 also provide live access to infrared and visible light video feeds to an end user accessing servers 140 through a client device 160, and further provide the ability for a user using client device 160 to review recorded video from the infrared and visible light feeds. That is, video is provided both live and recorded at the same time so that a user can navigate to video captured at previous points in time, for example to research the origins of a fault.

By monitoring power system 70, faults can be detected before an equipment failure or an associated hazard such as a fire breaks out. This allows for repairs to be made and saves the cost of damage associated with catastrophic failure. Moreover, environmental harm can be avoided in many cases. For example, fires at a lithium-ion battery energy storage facility can release toxic gases, including hydrogen fluoride, into the air, and the rate of release of hydrogen fluoride can increase with the application of water to suppress the fire. Thermal runaway makes lithium-ion battery fires difficult to suppress. As a result, identifying a fault before a fire breaks out has the potential to avoid significant potential harm to the environment and people near a lithium-ion battery energy storage facility.

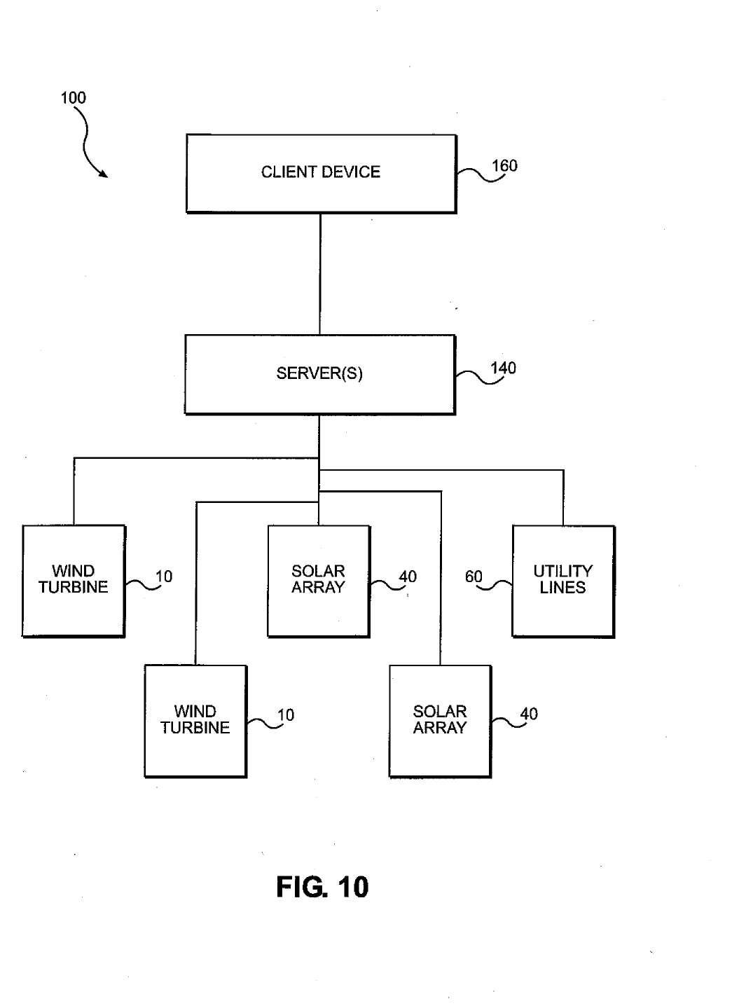

Referring now to FIG. 10, a conceptual diagram of a real-time fault monitoring system is illustrated and generally designated 100. Specific embodiments of system 100 were described in more particular detail as system 101 (see FIG. 3) and system 102 (see FIG. 9).

For illustrative purposes, system 100 is shown with a variety of monitored power systems, including wind turbines 10, solar arrays 40, and utility lines 60, each having its own camera 110 (not shown in FIG. 10) and wireless communication device 112 (not shown in FIG. 10) to connect to server 140 and ultimately provide data and alerts to client device 160 as described in detail above in connection with FIGS. 3 and 6. It will be apparent to one of ordinary skill in the art that system 100 is capable of working with additional types of power systems, such as transformers, switchgears, high voltage power panels, batteries, inverters, utility vaults, and other equipment in a variety of situations including power generation and distribution, manufacturing facilities, and other situations in which real-time fault monitoring may be useful. Since inclusion of each individual possible type of monitored power equipment in the diagram is not necessary for understanding the subject matter of the invention, they are not shown in FIG. 10; however, they would be connected to server 140 in the same manner as illustrated equipment, wind turbines 10, solar arrays 40, and utility lines 60 are connected, and more particularly in a configuration analogous to that shown in FIGS. 3 and 6.

The variety of monitored equipment is presented in FIG. 10 for illustrative purposes. A typical implementation may have a variety of equipment as illustrated, including types of monitored equipment not explicitly shown, or may have instances of only a single type of equipment. Each combination is fully contemplated herein.

For example, an electrical power distribution service may implement system 100 with cameras 110 (not shown in FIG. 10) to monitor utility lines 60, as well as to monitor switchgears and transformers (not shown) in substations. The service may purchase some of its power from a wind farm operating its own separate system 100 having multiple wind turbines 10 monitored. A manufacturing facility may implement system 100 with power panels as the monitored equipment, and, if partially solar powered, may also monitor solar inverters 44 (see FIG. 4) with system 100.

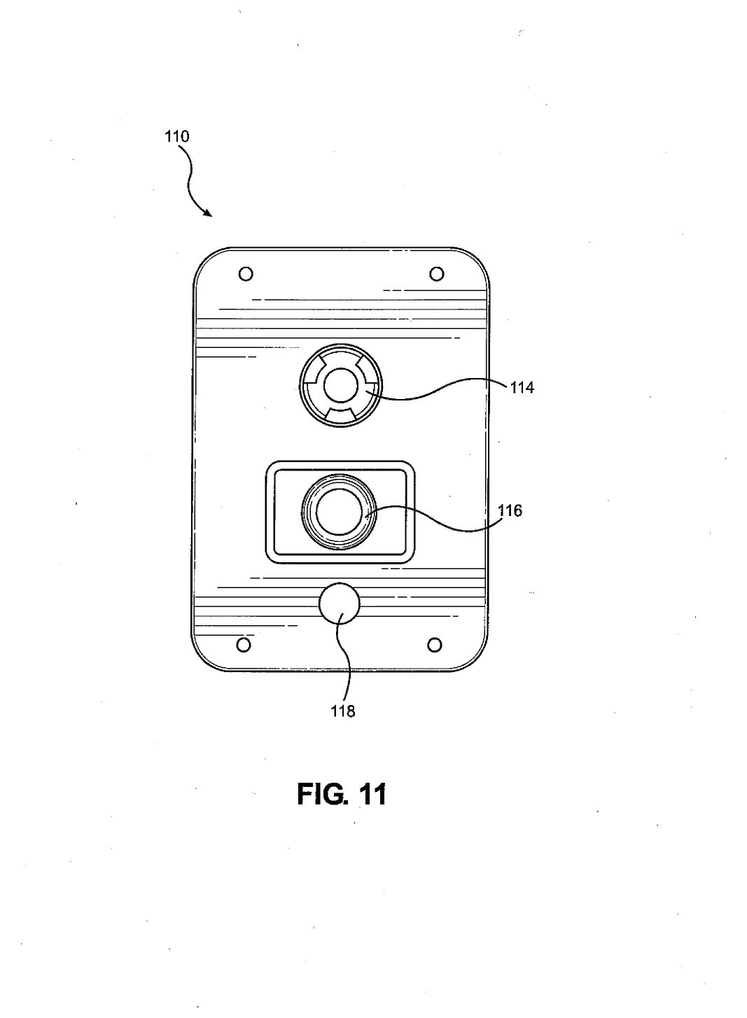

Referring now to FIG. 11, a preferred embodiment of camera 110 is a bi-spectrum camera with an infrared or thermal camera 114 and a visible light camera 116. An exemplary embodiment of thermal camera 114 is a bolometer that has a spectral range of approximately eight (8) to fourteen (14) micrometers and a resolution of at least two hundred fifty-six (256) pixels by one hundred ninety-two (192) pixels, scalable to at least seven hundred four (704) pixels by five hundred seventy-six (576) pixels, a thermal sensitivity of sixty-five (65) millikelvins or less at three hundred (300) kelvin, an aperture of F1.0, a horizontal viewing angle of ninety-five (95) degrees, and a vertical viewing angle of seventy-five (75) degrees.

An exemplary embodiment of visible light camera 116 uses a complementary metal-oxide semiconductor (CMOS) image sensor, such as those provided in conjunction with the mark SONY, and has an effective resolution of at least one thousand nine hundred twenty (1920) pixels by one thousand eighty (1080) pixels, a variable shutter speed, a variable aperture of up to F2.0, fixed focus, a horizontal viewing angle of one hundred thirty-six point two (136.2) degrees, and a vertical viewing angle of seventy-seven point three (77.3) degrees. It is functional at F1.2 aperture with at least 0.1 lux of illumination for color imaging, and at least 0.01 lux of illumination for black and white imaging.

Both thermal camera 114 and visible light camera 116 in the above-mentioned exemplary embodiments provide video of at least twenty-five (25) and thirty (30) frames per second.

Some preferred embodiments of camera 110 include an additional temperature detection sensor 118 capable of at least three temperature measurement rule types, including spot, line, and area temperature measurements at an operational range of negative forty (-40) degrees Fahrenheit to three hundred two (302) degrees Fahrenheit.

Preferred embodiments of camera 110 communicate with wireless communication device 112 (see FIG. 1) through an RJ-45 jack for an ethernet cable, a USB interface, or via video output through a BNC or RS485 interface. Over the ethernet interface Unicast streaming directly from camera 110 is supported. Embodiments with each possible combination of one or more of the above-mentioned interfaces are fully contemplated, as are the use of other interfaces known in the art.

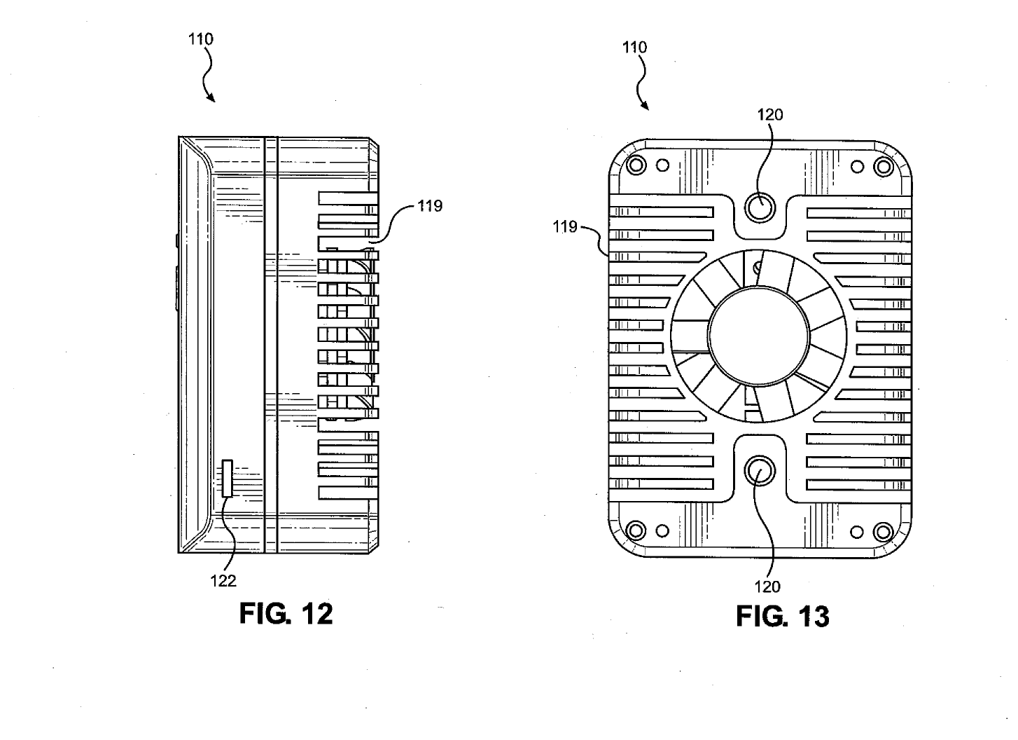

Referring now to FIG. 12, a side view of camera 110 is illustrated, showing ventilation slots 119 present to prevent overheating in some preferred embodiments. Preferred embodiments of camera 110 include a Secure Digital (SD) card port 122 or other port or connector for a removable mass storage device, allowing for data including video data from camera 110 to be stored and transferred without network access. This allows camera 110 to be operable during network outages or without a network (thus providing an “air gap” when security requirements necessitate one), and backup access to the data in case of loss from server 140 (shown in FIG. 10) or a network attack or other event that may raise questions to the reliability of video transferred to server 140 or client 160 (shown in FIG. 10).

Referring now to FIG. 13, mounting apertures 120 allow for camera 110 to be mounted directly to a wall or other existing structure, or to a separate mounting accessory. Some embodiments of such an accessory include an actuator, rail, or worm and gear system, a motorized panning and tilting bracket, a servo for tilting, or a combination thereof in order to allow remote-controlled movement and adjustment of the position and angle of camera 110.

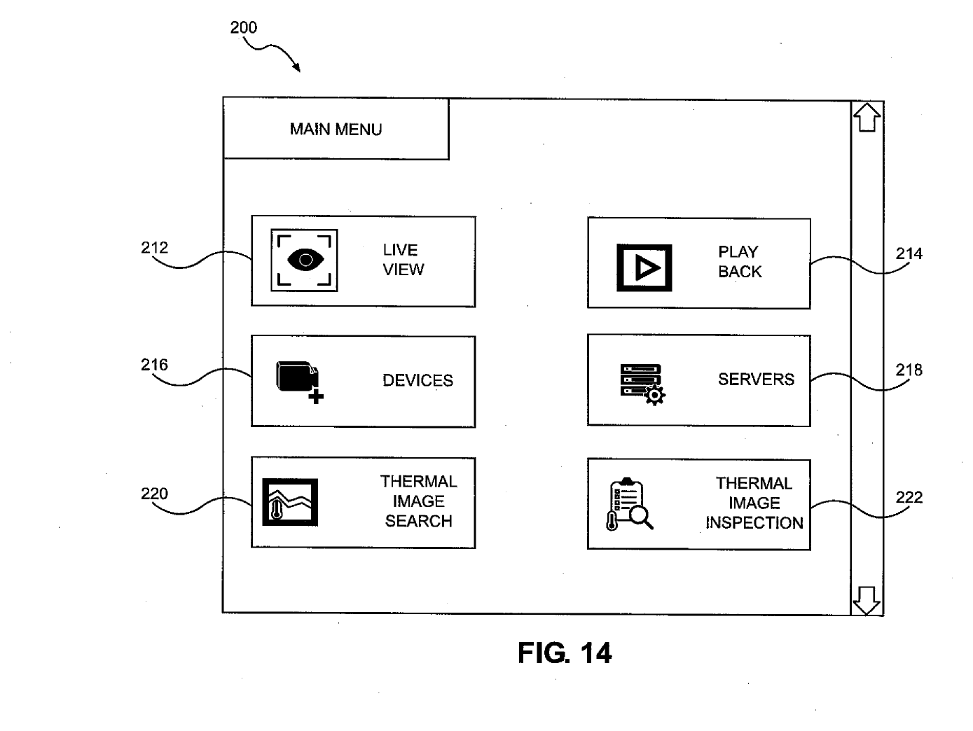

Referring now to FIG. 14, an exemplary user interface dashboard is illustrated and generally designated 200. Dashboard is displayed by client device 160 (shown in FIG. 9) as an application—such as a web application or mobile application—accessing services provided by servers 140 (shown in FIG. 9). Exemplary application elements include live view 212 through which a user views live video streams, play back 214 for viewing recorded video, such as to trace a fault back to its origin in time. Devices element 216 allows for configuration on monitoring of cameras 110 on separate wind turbines 10, for example, in preferred embodiments of system 100 (shown FIG. 9) in which multiple wind turbines 10 are present, each with its own camera 110 or cameras 110. Servers 218 element allows for configuration of the servers 140 (shown in FIG. 9). Thermal image search 220 element and thermal image inspection element 222 provide easier access for a user to find recorded images from a previous point in time.

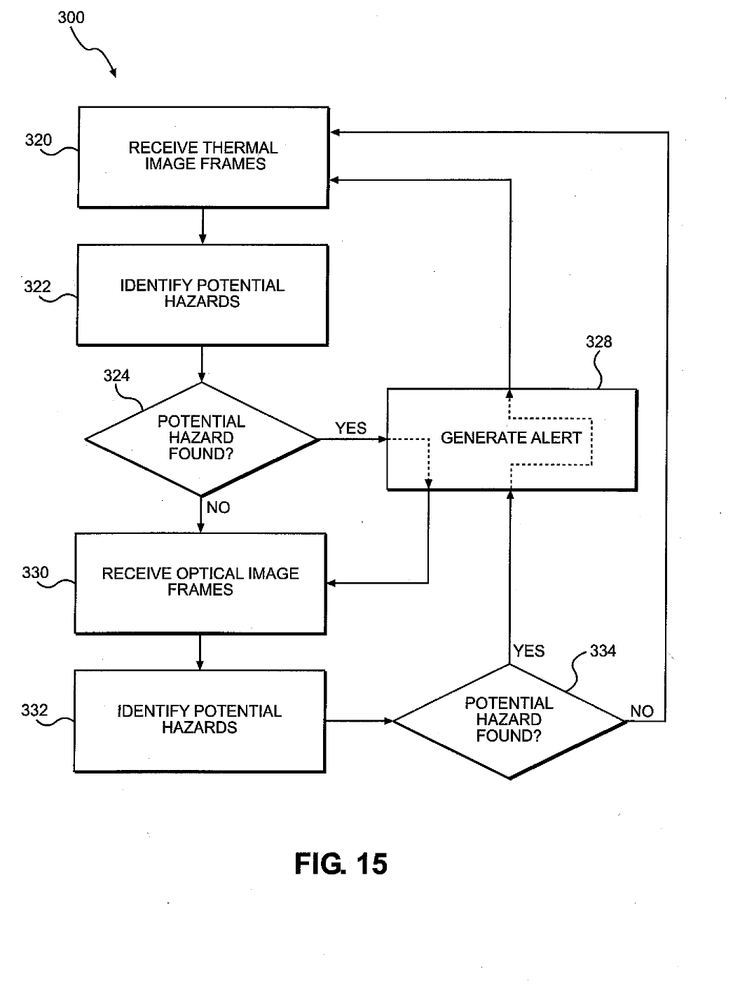

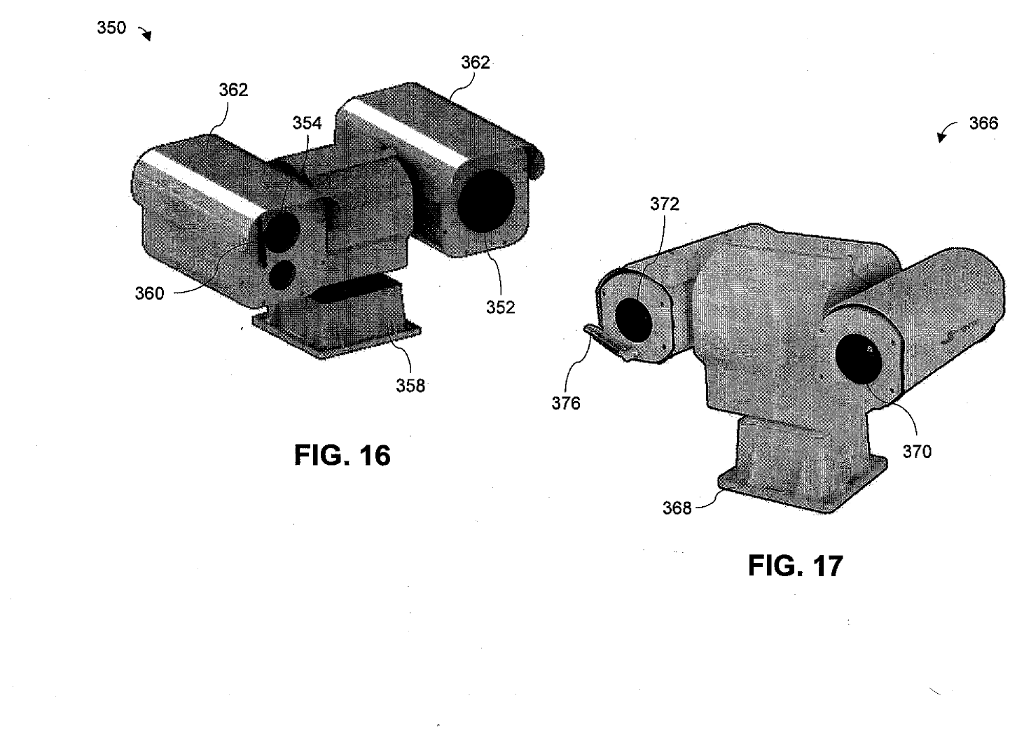

Referring now to FIG. 15, a simple diagram of a process 300 for identifying hazards is illustrated. Process 300 or a similar process is performed by server 140 (shown in FIG. 10) in preferred embodiments of real-time fault monitoring system 100 (shown in FIG. 10), including preferred embodiments of system 101 (shown in FIG. 3) and system 102 (shown in FIG. 9). Process 300 or a similar process is performed on client device 160 (shown in FIG. 10) in some alternate embodiments, and in some preferred embodiments in which camera 110 (shown in FIG. 11) provides imaging directly to a client device 160 (shown in FIG. 10) without intervening servers 140 (shown in FIG. 10). Indeed, some cameras, such as those shown in FIGS. 16-18, perform process 300 using instructions in firmware to detect hazards such as fire or ignition.

As video from the thermal camera 114 (shown in FIG. 11) is received in step 320, potential hazards are identified in step 322. The various pattern recognition techniques known in the art can be used in this step, but a preferred embodiment uses statistical techniques associated with machine learning to identify hazards. Upon finding a potential hazard in step 324, an alert is generated in step 328 and, in preferred embodiments, sent to a client device 160 (shown in FIG. 10) as discussed previously. The monitoring process 300 continues.

Video from the visible light camera 116 (shown in FIG. 11) is received in step 330 and analyzed to identify potential hazards in step 332. Step 332 is performed in the same manner as step 322, using computer vision techniques such as machine learning to identify hazards. When a potential hazard is found in step 334, an alert is generated in step 328 and, in preferred embodiments, sent to a client device 160 (shown in FIG. 10). The process 300 continues in a loop for continuous monitoring.

The steps of process 300 have been illustrated and described sequentially in order to provide a clear explanation of the process. It will, however, be apparent to a person of ordinary skill in the art that various steps of the process can be performed simultaneously. For example, video frames can continue to be received in steps 320 and 330 while previously received frames are analyzed in steps 322 and 332. Likewise, monitoring thermal video as described in steps 320, 322, and 324 can be performed concurrently with monitoring visible-light video as described in steps 330, 332, and 334. Embodiments that implement concurrency in the monitoring process and other computer processes are fully contemplated herein.

Referring now to FIGS. 16-18, some exemplary models of bi-spectrum cameras particularly suitable for outdoor use, such as in electrical substations or for wildfire monitoring, are illustrated. Each camera is a bi-spectrum camera with both a visible light imaging system and a radiometric infrared thermal imaging system. Preferred embodiments of the infrared thermal imaging system in each model use an uncooled microbolometer for imaging, such as vanadium oxide uncooled focal plane arrays in an exemplary embodiment, and provide 640x512 resolution. As a rule of thumb, at least three pixels are needed for the camera (working with a monitoring system) to accurately identify a spot of interest, such as a fire.

FIG. 16 shows camera 350, which has an infrared imaging system 352 and a visible light imaging system 354. In an exemplary embodiment, infrared imaging system 352 uses a 100mm thermal lens and can detect a person or a three-foot-by-three-foot fire up to two miles away. In another exemplary embodiment, infrared imaging system 352 uses a 25-105mm thermal lens, providing a zoom feature with infrared video, with a 200m variant providing detection of a one-foot-by-one-foot fire up to five miles away. In preferred embodiments, visible light imaging system 354 uses a lens system that provides 37x optical zoom. Camera 350 is mounted on a pan, tilt, and zoom (PTZ) base 358. Antenna 360 facilitates wireless communications to control camera 350, including pan, tilt, and zoom, features, and send video and image data from camera 350 to a server or end user.

FIG. 17 shows camera 366, also mounted on a PTZ base 368. Camera 366 has an infrared imaging system 370, a visible light imaging system 372, and an antenna 376 that facilitates wireless communications to control camera 368, including pan, tilt, and zoom, features, and send video and image data from camera 368 to a server or end user. A preferred embodiment of camera 366 provides at least 30x optical zoom for the visible light imaging system 372, and uses a 50mm thermal lens for infrared imaging system 370, providing person detection and one-foot-by-one-foot fire detection at up to a one-mile range. An alternative embodiment of camera 366 provides a 25mm thermal lens for infrared imaging system 370 and is suitable for relatively short-range wide areas.

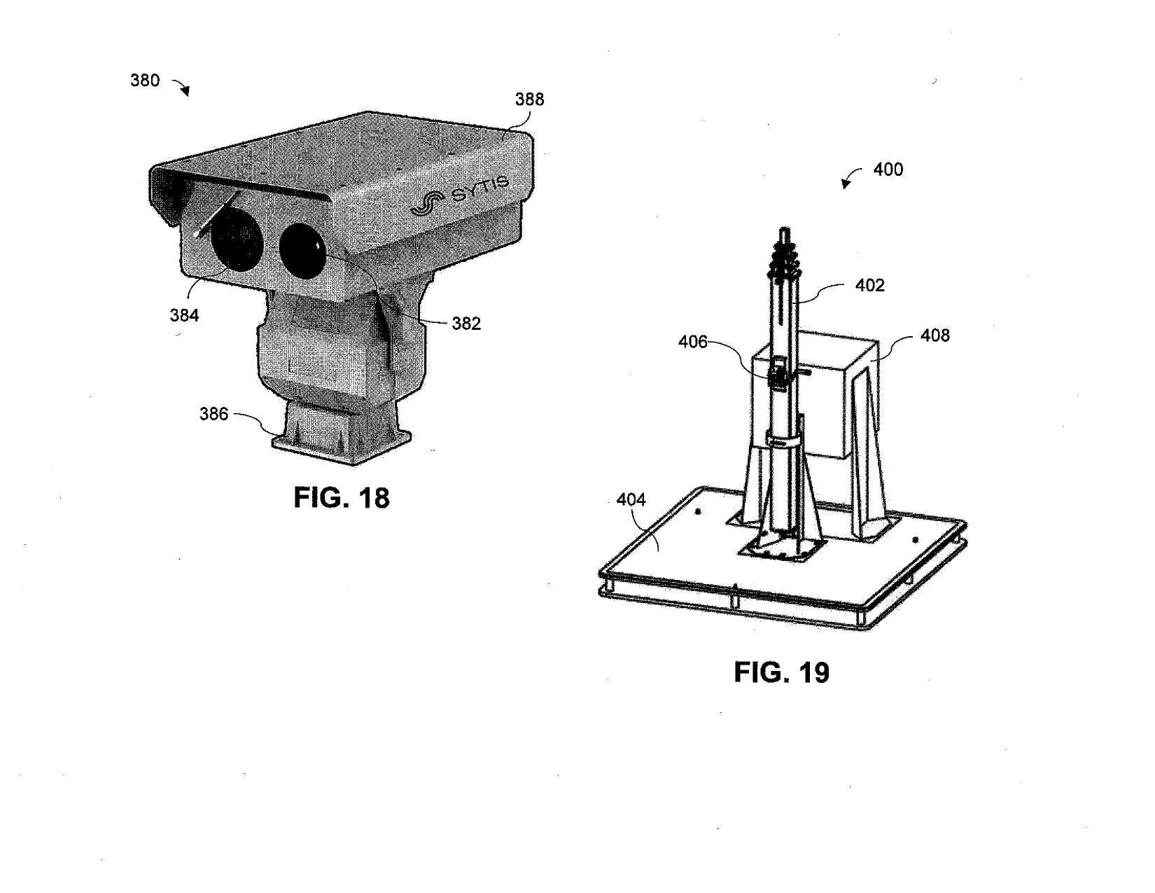

FIG. 18 shows camera 380, also with a visible light imaging system 382, an infrared imaging system 384, and a PTZ base 386. Drip lid 388 provides weatherproofing for camera 380.

Referring now to FIG. 19, a perspective view of a skid assembly for a semi-permanent or permanent camera installation for a monitoring system is illustrated and generally designated 400. Cameras forming part of a real-time incident monitoring system as described herein, such as camera 350, 366, or 380, can be mounted on an existing tower or other structure. Alternatively, skid assembly 400 provides a structure for supporting a camera assembly, which can be useful when no other appropriate structure is available, or when a stand-alone system is desired. Skid assembly 400 has a mast 402 mounted on a base 404. In a preferred embodiment, base 404 weighs about four thousand (4000) pounds, allowing skid assembly 400, when installed on-location with a camera assembly mounted on mast 402, to withstand up to one-hundred thirty (130) mile-per-hour winds. A winch 406 allows mast 402 to be extended to a desired height. Network box 408 provides communications capabilities for the camera system (not shown in this figure) mounted on mast 402.

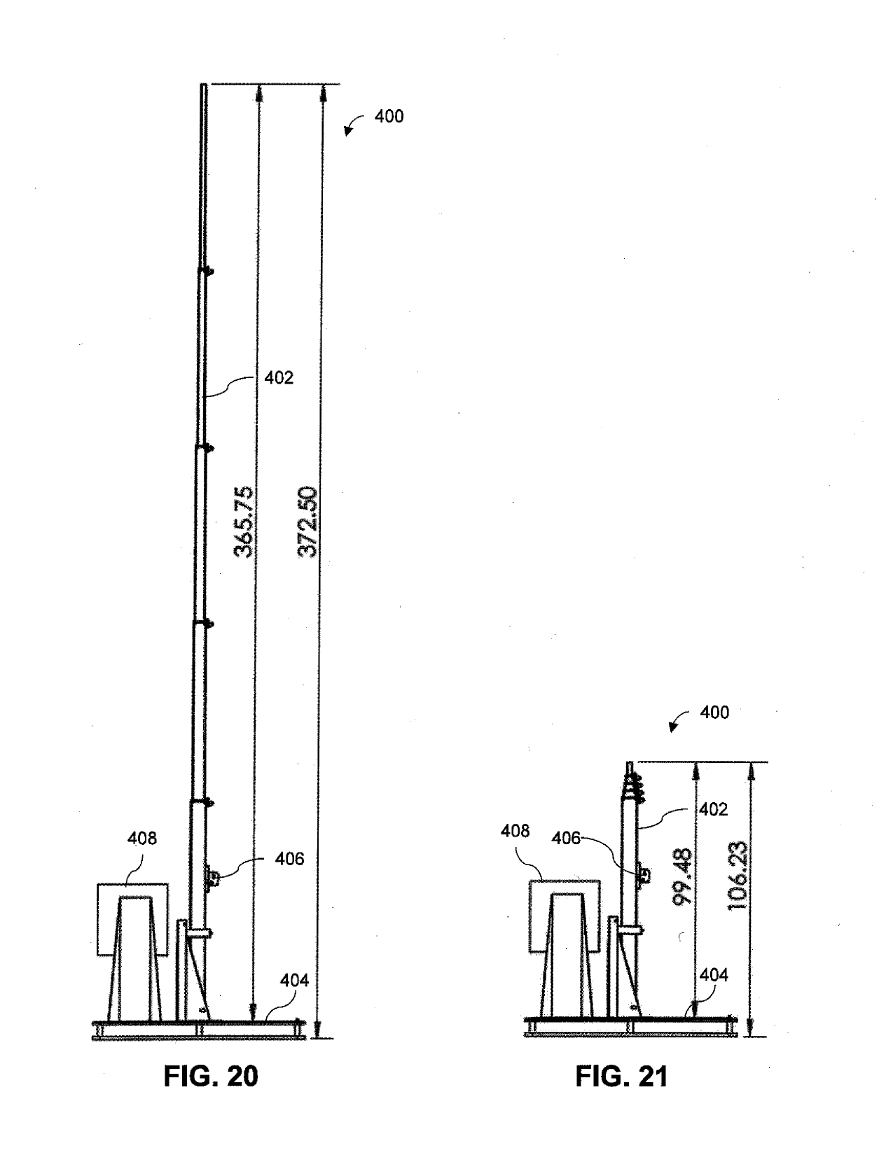

Referring now to FIG. 20, skid assembly 400 is illustrated with mast 402 in a fully extended configuration. In a preferred embodiment, this configuration raises the camera equipment about thirty and one-half feet, or three-hundred sixty-five point seventy-five (365.75) inches above the top of base 404.

Referring now to FIG. 21, a side view of skid assembly 400 is shown with mast 402 in a fully retracted configuration. In this configuration, in the preferred embodiment mentioned above, the top of mast 402 is a little over eight feet, at ninety-nine point forty-eight (99.48) inches above the top of base 404.

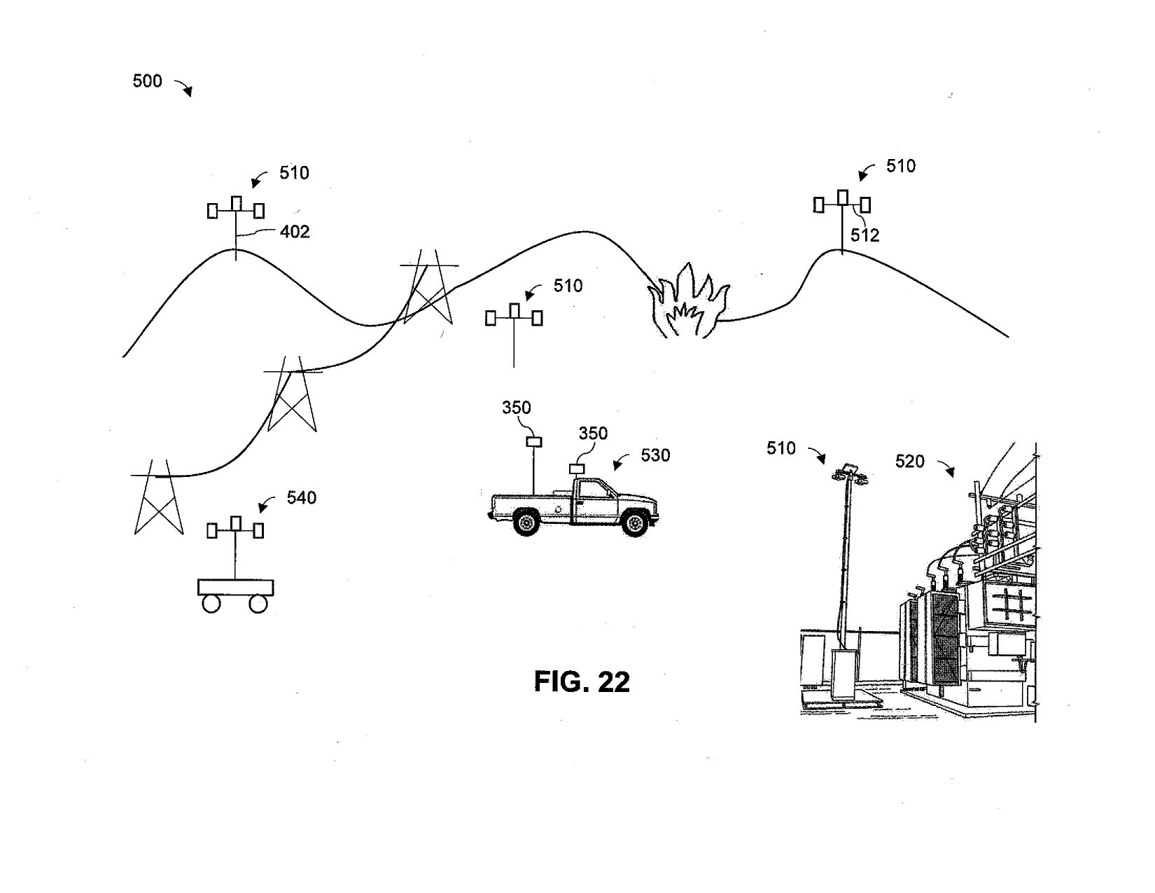

Referring now to FIG. 22, a system for wildfire monitoring is illustrated and generally designated 500. System 500 includes fixed camera installations 510 positioned to observe areas at risk for wildfires. In a preferred embodiment, an installation 510 has one or more cameras mounted on top of a skid assembly 400 (shown in FIGS. 19-21). For example, the exemplary embodiment illustrated has a beam 512 attached to the top of mast 402 to facilitate the mounting of three (3) cameras. For example, in some preferred embodiments, a camera 350 as illustrated in FIG. 16, or a camera 380 as illustrated in FIG. 18, functions as a primary camera centered along beam 512, with cameras 350 as illustrated in FIG. 16 or cameras 366 as illustrated in FIG. 17, or similar cameras as secondary cameras on each end of beam 512.

Installations 510 are positioned to monitor areas at risk for fire. The exemplary embodiment depicted includes mountaintop camera installations 510 mounted high to continuously monitor broad areas where wildfires commonly occur, as well as other camera installations 510 positioned to observe specific objects or structures that present a wildfire risk, such as power lines 514. Using the PTZ capabilities, cameras in installations 510 can rotate, move, and zoom as necessary to observe an incident that occurs, such as a fire 516 that breaks out, even if installation 510 was originally positioned to view a specific structure. Similarly, an installation 510 may generally be used for a purpose not directly related to wildfire monitoring, for example, monitoring hazards at an electric substation 520; the cameras on this installation 510 can be rotated, tilted, and zoomed as necessary to monitor fire 516, either for aiding emergency services, or simply for the relevant electric utility to ascertain risk to its own systems, or both.

In some embodiments, mobile bi-spectrum camera systems, such as truck-mounted cameras 530 and trailer-mounted cameras 540, provide additional monitoring support in the event of an incident such as wildfire 516.

While there have been shown what are presently considered to be preferred embodiments of the present invention, it will be apparent to those skilled in the art that various changes and modifications can be made herein without departing from the scope and spirit of the invention.

What is claimed is:

1. A wildfire monitoring system, comprising:
a server; and
a plurality of bi-spectrum camera installations, each comprising:
a visible light imaging device;
a thermal imaging device; and
a network device configured to receive video signals from the visible light imaging device and the thermal imaging device and provide the video signals to the server,
wherein the plurality of bi-spectrum camera installations are positioned to observe areas at risk for wildfires, and
wherein the server is configured to use artificial intelligence (AI) assisted pattern recognition to detect smoke and fire in the video signals, and to send a fire alert to one or more email recipients when fire is detected.

2. The wildfire monitoring system of claim 1, wherein the fire alert comprises a thermal image of a location where the fire is detected.

3. The wildfire monitoring system of claim 2, wherein the thermal image wherein the thermal image of the location where the fire is detected comprises a time stamp, a temperature reading, and an indicator in a portion of the thermal image where the AI recognized the fire.

4. The wildfire monitoring system of claim 1, wherein the server is configured to use AI assisted pattern recognition to recognize a person at risk from a nearby fire, and to send a person at risk alert to one or more email recipients.

5. The wildfire monitoring system of claim 1, wherein the network device of each bi-spectrum camera installation comprises an ethernet interface.

6. The wildfire monitoring system of claim 1, wherein the network device of each bi-spectrum camera installation comprises a cellular radio.

7. The wildfire monitoring system of claim 1, wherein the network device of each bi-spectrum camera installation comprises a satellite communications device.

8. The wildfire monitoring system of claim 1, wherein the thermal imaging device of each of the plurality of bi-spectrum camera installations comprises a variable focus infrared lens with a twenty-five to one-hundred-five millimeter focal range.

9. A wildfire monitoring system, comprising:
a server;
a plurality of fixed bi-spectrum camera installations positioned to observe areas at risk for wildfires, each comprising:
a visible light imaging device;
a thermal imaging device; and
a network device configured to receive video signals from the visible light imaging device and the thermal imaging device and provide the video signals to the server; and
one or more mobile bi-spectrum camera assemblies, each comprising:
a visible light imaging device;
a thermal imaging device; and
a network device configured to receive video signals from the visible light imaging device and the thermal imaging device and provide the video signals to the server,
wherein the server is configured to use artificial intelligence (AI) assisted pattern recognition to detect smoke and fire in the video signals, and to send a fire alert to one or more email recipients when fire is detected.

10. The wildfire monitoring system of claim 9, wherein the fire alert comprises a thermal image of a location where the fire is detected.

11. The wildfire monitoring system of claim 10, wherein the thermal image wherein the thermal image of the location where the fire is detected comprises a time stamp, a temperature reading, and an indicator in a portion of the thermal image where the AI recognized the fire.

12. The wildfire monitoring system of claim 9, wherein the server is configured to use AI assisted pattern recognition to recognize a person at risk from a nearby fire, and to send a person at risk alert to one or more email recipients.

13. The wildfire monitoring system of claim 9, wherein the network device of each of the plurality of fixed bi-spectrum camera installations comprises an ethernet interface.

14. The wildfire monitoring system of claim 9, wherein the network device of each of the one or more mobile bi-spectrum camera assemblies comprises a cellular radio.

15. A wildfire monitoring system, comprising:
a server; and
a plurality of bi-spectrum camera installations, each comprising:
a primary camera having a visible light imaging device and a thermal imaging device;
two secondary cameras, each having a visible light imaging device and a thermal imaging device; and
a network device configured to receive video signals from the visible light imaging device and the thermal imaging device and provide the video signals to the server,
wherein the plurality of bi-spectrum camera installations are positioned to observe areas at risk for wildfires, and
wherein the server is configured to use artificial intelligence (AI) assisted pattern recognition to detect smoke and fire in the video signals, and to send a fire alert to one or more email recipients when fire is detected.

16. The wildfire monitoring system of claim 15, wherein the fire alert comprises a thermal image of a location where the fire is detected.

17. The wildfire monitoring system of claim 16, wherein the thermal image wherein the thermal image of the location where the fire is detected comprises a time stamp, a temperature reading, and an indicator in a portion of the thermal image where the AI recognized the fire.

18. The wildfire monitoring system of claim 15, wherein the server is configured to use AI assisted pattern recognition to recognize a person at risk from a nearby fire, and to send a person at risk alert to one or more email recipients.

19. The wildfire monitoring system of claim 15, wherein the primary camera of each bi-spectrum camera installation comprises a variable focus infrared lens with a twenty-five to one-hundred-five millimeter focal range.

20. The wildfire monitoring system of claim 15, further comprising one or more mobile bi-spectrum camera assemblies, each comprising:
a visible light imaging device;
a thermal imaging device; and
a network device configured to receive video signals from the visible light imaging device and the thermal imaging device and provide the video signals to the server.
